(19) United States
(12) Patent Application Publication
(10) Pub. No.: US 2025/0259656 A1
(43) Pub. Date: Aug. 14, 2025

(54) LOW-POWER LOW-NOISE DATA STORAGE ARRAY COOLING

(71) Applicant: Western Digital Technologies, Inc., San Jose, CA (US)

(72) Inventors: Hussam Zebian, Milpitas, CA (US); Toshiki Hirano, San Jose, CA (US)

(21) Appl. No.: 18/441,899

(22) Filed: Feb. 14, 2024

(51) Int. Cl. G11B 33/12; G11B 33/14

(52) U.S. Cl. CPC G11B 33/128; G11B 33/142

(57) ABSTRACT

A data storage system having data storage devices (DSDs) housed in rows in an enclosure further includes a series of funnel structures within which a respective row of DSDs is positioned, where the funnel structures are configured successively wider from front to back to direct airflow through the respective row to a successively wider central exhaust channel. The system may further include an upper wall structure with a deflector portion configured to direct airflow from above down to a back section of the DSDs, side channels extending beyond the deflector portion toward the back to direct airflow down to successive rows of DSDs beyond the deflector portion, and a central channel extending from the deflector portion toward the front and over a cutout portion of a ceiling structure and configured to receive exhaust airflow from a front section of the DSDs via the cutout portion.

### FIELD OF EMBODIMENTS

Embodiments of the invention may relate generally to arrays of storage devices, and particularly to guiding cooling air within a storage device array.

### BACKGROUND

As networked computing systems grow in numbers and capability, there is a need for more data storage system capacity. Cloud computing and large-scale data processing further increase the need for digital data storage systems that are capable of transferring and holding significant amounts of data. One approach to providing sufficient data storage in data centers is the use of arrays of data storage devices typically configured and provisioned as one or more data storage systems. Many data storage devices can be housed in an electronics enclosure, which is typically a modular unit that can hold and operate independent data storage devices in an array, computer processors, routers and other electronic equipment. For example, one such approach to vast data storage is referred to as a JBOD (“Just a Bunch of Disks”, or “Just a Bunch of Drives”), which is typically a collection of hard disk drives (HDDs) that may be exposed as independent devices or combined to operate as one logical volume. A similar approach in the context of solid-state storage is referred to as a JBOF (“Just a Bunch of Flash”), which is typically a collection of solid-state drives (SSDs). Data centers may include many such rack-mountable data storage systems mounted within respective shelves of a larger enclosure, often referred to as a “rack”, and which are used to store massive amounts of data. Temperature management within such a rack-mountable enclosure is of critical importance for proper and reliable operational capabilities of a data center and data storage system, generally, and of the constituent data storage devices, particularly.

Any approaches that may be described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

### BRIEF DESCRIPTION OF THE DRAWINGS

Embodiments are illustrated by way of example, and not by way of limitation, in the figures of the accompanying drawings and in which like reference numerals refer to similar elements and in which:

FIG. 1A is a plan view illustrating a hard disk drive (HDD), according to an embodiment;

FIG. 1B is a block diagram illustrating a solid-state drive (SSD), according to an embodiment;

FIG. 2A is a block diagram side view illustrating a data storage system, according to an embodiment;

FIG. 2B is a first block diagram top view illustrating the data storage system of FIG. 2A, according to an embodiment;

FIG. 2C is a second block diagram top view illustrating the data storage system of FIG. 2A, according to an embodiment;

FIG. 2D is a third block diagram top view illustrating the data storage system of FIG. 2A, according to an embodiment;

FIG. 3A is a block diagram side view illustrating front section airflow for the data storage system of FIG. 2A, according to an embodiment;

FIG. 3B is a first block diagram top view illustrating front section airflow for the data storage system of FIG. 2A, according to an embodiment;

FIG. 3C is a second block diagram top view illustrating front section airflow for the data storage system of FIG. 2A, according to an embodiment;

FIG. 4A is a block diagram side view illustrating back section airflow for the data storage system of FIG. 2A, according to an embodiment;

FIG. 4B is a first block diagram top view illustrating back section airflow for the data storage system of FIG. 2A, according to an embodiment;

FIG. 4C is a second block diagram top view illustrating back section airflow for the data storage system of FIG. 2A, according to an embodiment; and

FIG. 5 is a block diagram top view illustrating I/O module airflow for the data storage system of FIG. 2A, according to an embodiment.

### DETAILED DESCRIPTION

Generally, approaches to data storage array cooling air guiding features are described. In the following description, for the purposes of explanation, numerous specific details are set forth to provide a thorough understanding of the embodiments of the invention described herein. It will be apparent, however, that the embodiments of the invention described herein may be practiced without these specific details. In other instances, well-known structures and devices may be shown in block diagram form to avoid unnecessarily obscuring the embodiments of the invention described herein.

### INTRODUCTION

### Terminology

References herein to “an embodiment”, “one embodiment”, and the like, are intended to mean that the particular feature, structure, or characteristic being described is included in at least one embodiment of the invention. However, instances of such phrases do not necessarily all refer to the same embodiment,

The term “substantially” will be understood to describe a feature that is largely or nearly structured, configured, dimensioned, etc., but with which manufacturing tolerances and the like may in practice result in a situation in which the structure, configuration, dimension, etc. is not always or necessarily precisely as stated. For example, describing a structure as “substantially vertical” would assign that term its plain meaning, such that the sidewall is vertical for all practical purposes but may not be precisely at 90 degrees throughout.

While terms such as “optimal”, “optimize”, “minimal”, “minimize”, “maximal”, “maximize”, and the like may not have certain values associated therewith, if such terms are used herein the intent is that one of ordinary skill in the art would understand such terms to include affecting a value, parameter, metric, and the like in a beneficial direction consistent with the totality of this disclosure. For example, describing a value of something as “minimal” does not require that the value actually be equal to some theoretical minimum (e.g., zero), but should be understood in a practical sense in that a corresponding goal would be to move the value in a beneficial direction toward a theoretical minimum.

### CONTEXT

Recall that many data storage devices can be housed in a shared enclosure, such as with a JBOD for a non-limiting example, and that data centers may include many such rack-mountable data storage systems mounted within a rack. Temperature management within such a rack-mountable enclosure is of critical importance for proper and reliable operational capabilities. Data centers consume huge amounts of power and operators are interested in ways to reduce power consumption, such as to save operating cost and to reduce environmental impact. Note that a significant portion of the power consumed by a data center is for equipment cooling purposes, e.g., for every watt of equipment power usage about a watt is used to cool the equipment. Generally, data center owners and operators seem to prefer high-density packing of data storage devices within a data storage system. However, high-density systems typically require higher cooling fan power, and powerful fans generate significant acoustic noise and corresponding vibration, which can degrade hard disk drive performance and may even prevent such system use except in dedicated locations such as closed rooms. Thus, the cooling needs of a data storage system remain a challenge, especially in view of the trend toward high-density storage systems in which many devices are packed closely together.

Cooling Airflow Guiding Structures within Data Storage System Enclosure

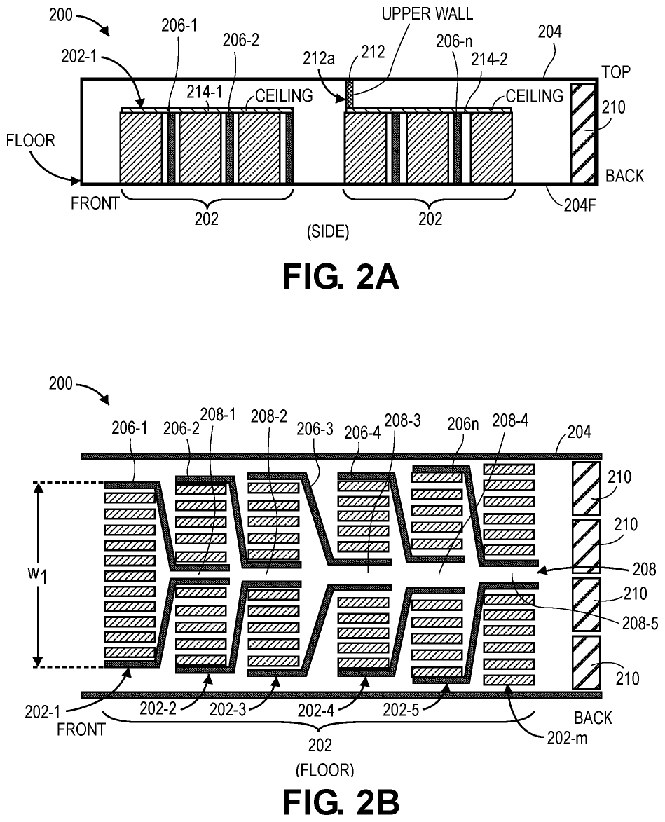

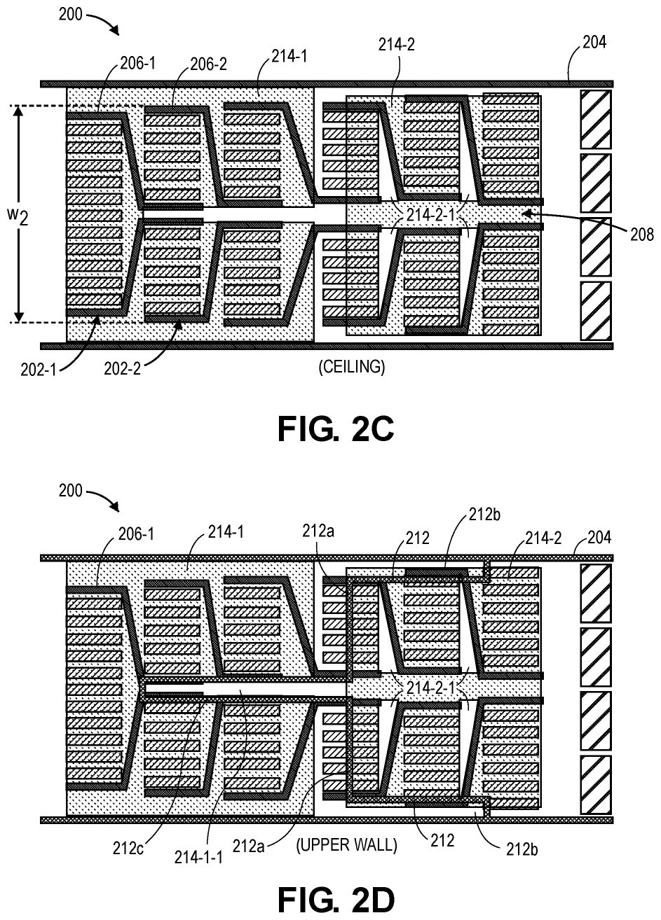

FIG. 2A is a block diagram side view illustrating a data storage system, FIG. 2B is a first block diagram top view illustrating the data storage system of FIG. 2A, FIG. 2C is a second block diagram top view illustrating the data storage system of FIG. 2A, and FIG. 2D is a third block diagram top view illustrating the data storage system of FIG. 2A, all according to embodiments. In particular, FIG. 2A is a simplified cross-sectional side view diagram along the width of the data storage system and illustrates a floor, an upper wall, and a ceiling over each of a plurality of sets or groupings of data storage devices. FIG. 2B is a simplified diagram illustrating the data storage system of FIG. 2A at the “floor” level, FIG. 2C is a simplified diagram illustrating the data storage system of FIG. 2A at the “ceiling” level, and FIG. 2D is a simplified diagram illustrating the data storage system of FIG. 2A at the “upper wall” level.

Data storage system 202 (“DSS 200”) comprises a plurality of data storage devices 202, such as hard disk drives (HDDs) and/or solid-state drives (SSDs), housed in a plurality of rows in an enclosure 204. According to an embodiment, within the enclosure 204, DSS 200 further comprises one or more cooling airflow guiding structural features, including a first funnel structure 206-1 extending from a floor 204f of the enclosure 204, and within which at least part of a first row 202-1 of the data storage devices 202 is positioned, where the first funnel structure 206-1 has a first width w1 and is configured to direct airflow past the first row 202-1 to a first central exhaust channel 208-1. DSS 200 further comprises a second funnel structure 206-2 extending from the floor 204f of the enclosure 204, and within which at least part of a second row 202-2 of the data storage devices 202 is positioned, where the second funnel structure 206-2 has a second width w2 that is greater (i.e., wider) than the first width w1 and is configured to direct airflow past the second row 202-2 to a second central exhaust channel 208-2 substantially colinear with the first exhaust channel 208-1. According to an embodiment, the second exhaust channel 208-2 is wider than the first exhaust channel 208-1, thus enabling increasingly more exhaust (e.g., warm) airflow from front to back as the rows are traversed. According to an embodiment, DSS 200 further comprises one or more cooling fans 210, depicted here at the back of the enclosure 204 for purposes of example. According to an embodiment, the cooling fans 210 are constituent to one or more power supply unit (PSU). That is, with four appropriately sized PSU cooling fans (for a non-limiting example, around 3.5 Watt each), the desired airflow and redundancy for DSS 200 is considered achievable without the need for additional cooling fans.

Stated otherwise, DSS 200 comprises a series of funnel structures 206-1, 206-2, 206-3, 206-4 through 206-n, where n represents an arbitrary number of funnel structures that may vary from implementation to implementation, extending upward from the floor 204f of the enclosure 204 and within which a respective row 202-1, 202-2 through 202-m of data storage devices 202 is positioned, where m represents an arbitrary number of rows that may vary from implementation to implementation. The funnel structures 206-1 through 206-n are configured successively wider from a front toward a back of the enclosure 204 to direct airflow past each respective row 202-1, 202-2 through 202-m to a successively wider central exhaust channel 208. The successively wider funnel structures enable airflow intake to respective successive rows of devices, and in view of decreasing air pressure in the direction from front to back as the rows are traversed. Note that the cooling airflow system may be effectively run in reverse, where the airflow inlet would be the central channel 208 (i.e., back-to-front the channel would be a convergent channel) and the airflow outlet would be the two side channels outboard of the series of funnel structures 206-1 through 206-n (back-to-front these side channels would be divergent).

With reference to FIG. 2D, according to an embodiment DSS 200 further comprises an upper wall structure 212 positioned above the data storage devices 202 and extending to an enclosure top. The upper wall structure 212 is configured at least in part to effectively or functionally separate a first set of rows (e.g., three rows 202-1 through 202-3 depicted here for purposes of example; see, e.g., FIG. 2B) of data storage devices 202, including the aforementioned first row 202-1 and second row 202-2, from a second set of rows (e.g., three rows 202-4 through 202-m depicted here for purposes of example; see, e.g., FIG. 2B) of data storage devices 202. According to an embodiment, the upper wall structure comprises a deflector portion 212a positioned over a first row of data storage devices of the second set of rows 202-4 through 202-m, which is configured to direct or guide the airflow from above the devices down to the second set of rows 202-4 through 202-m.

With reference to FIG. 2D, according to an embodiment the upper wall structure 212 of DSS 200 further comprises at least one side channel 212b (e.g., two side channels 212b depicted here for purposes of example) extending beyond the deflector portion 212a in a direction toward the back of the enclosure 204. The side channel 212b is configured to direct airflow from above down to one or more successive rows of data storage devices, beyond the first row, of the second set of rows (e.g., rows 202-5 through 202-m; see, e.g., FIG. 2B).

According to an embodiment, DSS 200 further comprises a first ceiling structure 214-1 (FIGS. 2C-2D) over the first set of rows 202-1 through 202-3, and a second ceiling structure 214-2 (FIGS. 2C-2D) over the second set of rows 202-4 through 202-m. Such ceiling structures facilitate maintaining some degree of separation or isolation of relatively cooler cooling airflow, e.g., from the storage device “bays” under each respective ceiling, from relatively warmer exhaust airflow, e.g., from above the storage device “bays” over each respective ceiling to which at least some of the exhaust air is directed or enabled to flow.

According to an embodiment, the upper wall structure 212 further comprises a central channel 212c (FIG. 2D) extending in a direction toward the front of the enclosure 204 and over a cutout portion 214-1-1 (FIG. 2D) of the first ceiling structure 214-1. The central channel 212c of the upper wall structure 212 is configured to receive exhaust airflow from first set of rows 202-1 through 202-3 to above the first set of rows via the cutout portion 214-1-1 of the first ceiling 214-1. Furthermore and according to an embodiment, the second ceiling structure 214-2 also comprises at least one cutout portion 214-2-1 configured to enable exhaust airflow from the second set of rows 202-4 through 202-m to above the second set of rows beyond the deflector portion 212a of the upper wall structure 212 in a direction toward the back of the enclosure 204. According to a related embodiment, the at least one cutout portion 214-2-1 of the second ceiling structure 214-2 comprises a cutout portion 214-2-1 corresponding to each of multiple rows of the second set of rows 202-4 through 202-m, as depicted as triangular portions in FIGS. 2C-2D. Each cutout portion 214-2-1 is positioned beyond a respective row in a direction toward the back of the enclosure 204, as depicted in FIGS. 2C-2D, and configured to enable exhaust airflow from the respective row.

Note that the entire array of drives and the motherboard they are mounted on may be elevated, such that the gap between drives 202a-202m and enclosure 204 (here, the bottom rather than the top) exists at the basement and not the ceiling. All else would effectively be the same, except that inlet fresh air plenum(s) and exhaust plenum(s) would be positioned below the drives 202a-202m rather than above them. Such a configuration may enable the utilization of more air gaps that are inherently existent below the motherboard, but would likely rely on cutouts to the motherboard which is considered undesirable.

### Cooling Airflow Diagrams for Front Section of Devices

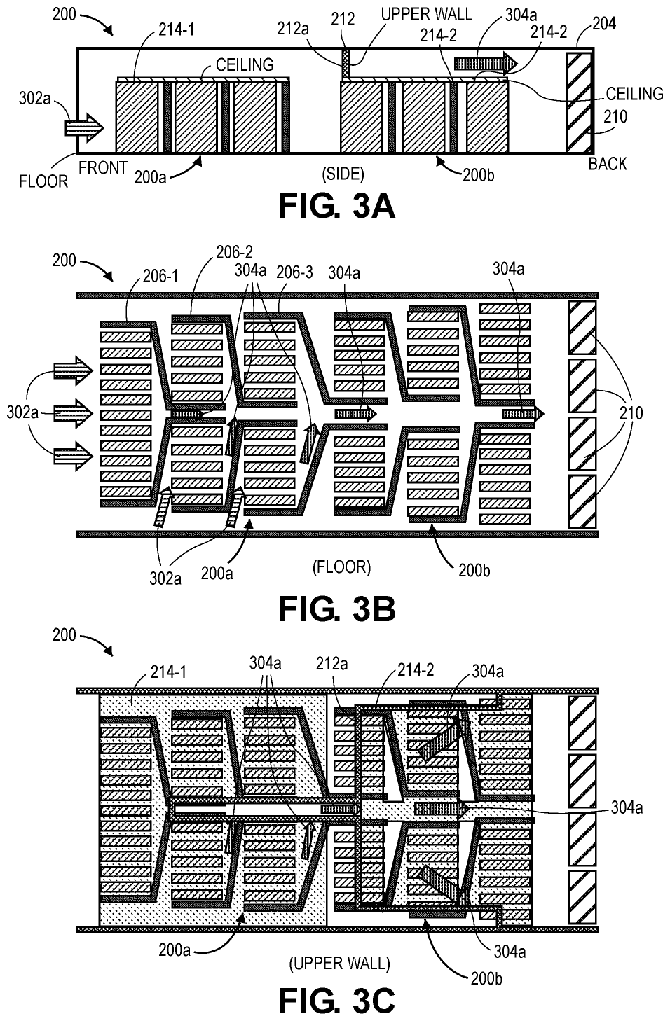

FIG. 3A is a block diagram side view illustrating front section airflow for the data storage system of FIG. 2A, FIG. 3B is a first block diagram top view illustrating front section airflow for the data storage system of FIG. 2A, and FIG. 3C is a second block diagram top view illustrating front section airflow for the data storage system of FIG. 2A, all according to embodiments. In particular, FIG. 3A is a simplified cross-sectional side view diagram along the width of the data storage system 200 similar to FIG. 2A, and illustrates a floor, an upper wall, and a ceiling over each of the sets or groupings of data storage devices, e.g., a front (or “first”) section and a back (or “second”) section. FIG. 3B is a simplified diagram illustrating the data storage system of FIG. 2A at the “floor” level similar to FIG. 2B, and FIG. 3C is a simplified diagram illustrating the data storage system of FIG. 2A at the “upper wall” level similar to FIG. 2D. FIGS. 3A-3C are set forth to aid in understanding the general effect of the aforementioned structures on the internal airflow. In each, block arrows having a horizontal cross-hatching are used to represent relatively cool (e.g., blue) cooling airflow and block arrows having a vertical cross-hatching are used to represent relatively warm (e.g., red) exhaust airflow.

FIG. 3A depicts relatively cool airflow 302a coming into enclosure 204 of DSS 200 and flowing through a front section 200a of DSS 200, such as equipment cooling airflow generated by one or more fan 210. Here, fan 210 is shown at the back of enclosure 204 with the cool airflow 302a entering at the front of enclosure 204, for purposes of example. However, such positioning may vary or may be reversed. FIG. 3A further depicts relatively warm airflow 304a flowing from the front section 200a into and along the central channel 212c (FIG. 2D) of upper wall 212 (FIGS. 2A, 2D) via cutout portion 214-1-1 (FIG. 2D) of ceiling 214-1, and over a back section 200b of DSS 200, i.e., over ceiling 214-2 and behind or beyond deflector portion 212a of upper wall 212.

FIG. 3B depicts, generally at the floor level, the relatively cool airflow 302a coming into enclosure 204 of DSS 200, and particularly into each funnel structure 206-1, 206-2, 206-3 (FIG. 2B) (including into the side inlet/intake portions of funnel structure 206-2, 206-3), and flowing through the front section 200a of rows 202-1, 202-2, 202-3 of data storage devices 202 (see, e.g., FIG. 2B) of DSS 200. FIG. 3B further depicts relatively warm airflow 304a flowing to each respective central exhaust channel 208-1, 208-2, 208-3 (FIG. 2B), collectively central exhaust channel 208 (FIGS. 2B-2C), and out the back via multiple fans 210.

FIG. 3C depicts, generally at the upper wall level, the relatively warm airflow 304a flowing upward from the front section 200a and into the central channel 212c (FIG. 2D) of upper wall 212 (FIGS. 2A, 2D) via cutout portion 214-1-1 (FIG. 2D) of ceiling 214-1. FIG. 3C further depicts the relatively warm airflow 304a continuing to flow over the back section 200b from the front section 200a, over ceiling 214-2 beyond deflector portion 212a of upper wall 212.

### Cooling Airflow Diagram for Input/Output Module

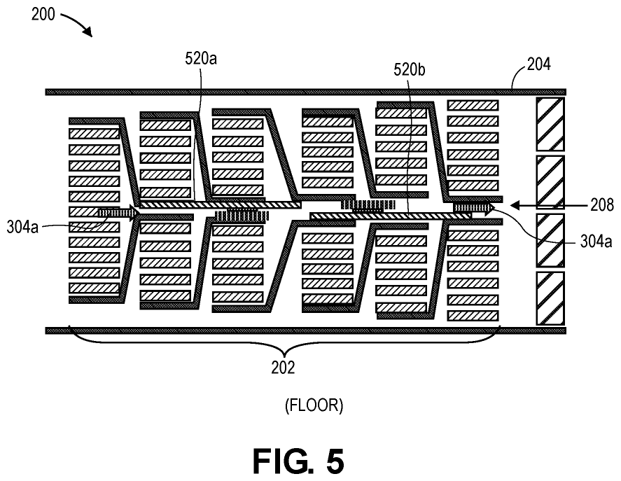

FIG. 5 is a block diagram top view illustrating I/O module airflow for the data storage system of FIG. 2A, according to an embodiment. According to an embodiment, DSS 200 further comprises at least one I/O (Input/Output) module 520a, 520b positioned within the central exhaust channel 208, which generally enable connectivity and communication with the data storage devices 202. Each I/O module 520a, 520b is positioned centrally within the enclosure 204 to minimize latency with the data storage devices 202, which is relative to the distance between I/O module 520 and the data storage devices 202 with which they are in communication. Furthermore, the I/O modules 520a, 520b are staggered relative to each side of the central exhaust channel 208 to minimize the impact on the warm airflow 304a through the central exhaust channel 208.

### Cooling Airflow Diagrams for Back Section of Devices

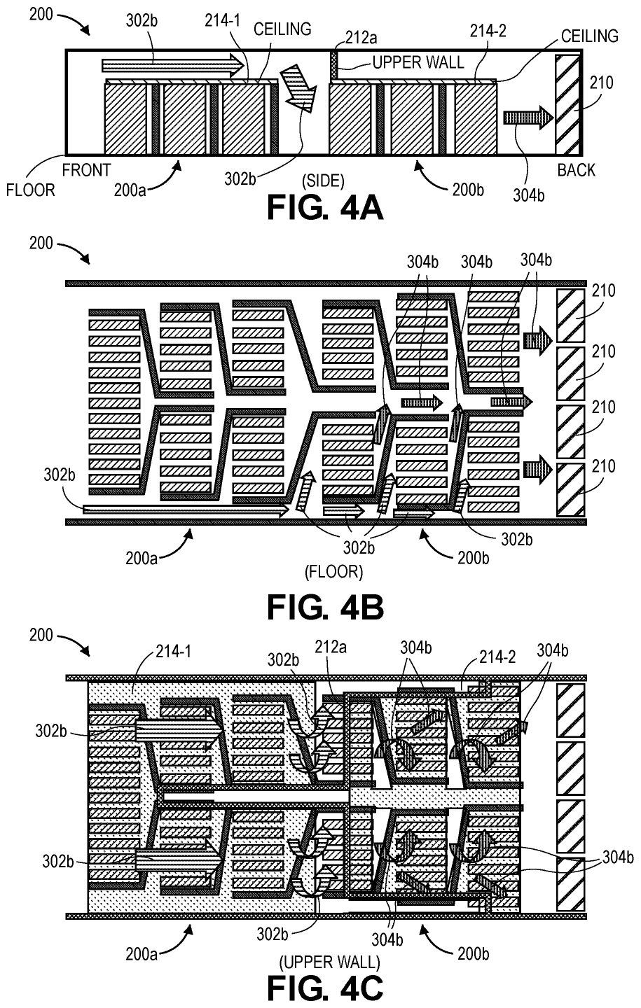

FIG. 4A is a block diagram side view illustrating second section airflow for the data storage system of FIG. 2A, FIG. 4B is a first block diagram top view illustrating second section airflow for the data storage system of FIG. 2A, and FIG. 4C is a second block diagram top view illustrating second section airflow for the data storage system of FIG. 2A, all according to embodiments. In particular, FIG. 4A is a simplified cross-sectional side view diagram along the width of the data storage system 200 similar to FIG. 2A, and illustrates a floor, an upper wall, and a ceiling over each of the sets or groupings of data storage devices, e.g., a front (or “first”) section and a back (or “second”) section. FIG. 4B is a simplified diagram illustrating the data storage system of FIG. 2A at the “floor” level similar to FIGS. 2B, 3B; and FIG. 4C is a simplified diagram illustrating the data storage system of FIG. 2A at the “upper wall” level similar to FIGS. 2D, 3C. FIGS. 4A-4C are set forth to aid in understanding the general effect of the aforementioned structures on the internal airflow. In each, block arrows having a horizontal cross-hatching are used to represent relatively cool (e.g., blue) cooling airflow and block arrows having a vertical cross-hatching are used to represent relatively warm (e.g., red) exhaust airflow.

FIG. 4A depicts relatively cool airflow 302b flowing over the ceiling 214-1 of front section 200a of DSS 200, such as equipment cooling airflow generated by one or more fan 210, and then flowing downward to the back section 200b under the guidance or deflection of the deflector portion 212a of upper wall 212. FIG. 4A further depicts relatively warm airflow 304b flowing from the back section 200b and out the back via fan 210.

FIG. 4B depicts, generally at the floor level, the relatively cool airflow 302b coming into enclosure 204 of DSS 200 and flowing past funnel structures 206-1, 206-2, 206-3 (FIG. 2B) along the increasingly narrow side channels of the front section 200a and into the side inlet/intake portions of funnel structure 206-4 through 206-n (FIG. 2B) of the back section 200b, and flowing through the back section 200b of rows 202-4, 202-5, 202-m of data storage devices 202 (see, e.g., FIG. 2B) of DSS 200. FIG. 4B further depicts the relatively warm airflow 304b flowing to each respective central exhaust channel 208-4, 208-5 (FIG. 2B) of each funnel structure 206-4 through 206-n (FIG. 2B) of the back section 200b, collectively central exhaust channel 208 (FIGS. 2B-2C), and out the back via multiple fans 210.

FIG. 4C depicts, generally at the upper wall level, the relatively cool airflow 302b flowing over the front section 200a and downward to the back section 200b under the guidance or deflection of the deflector portion 212a of upper wall 212. FIG. 4C further depicts the relatively warm airflow 304b flowing upward via one or more cutout 214-2-1 of ceiling 214-2 of back section 200b and over the ceiling 214-2 of back section 200b beyond deflector portion 212a of upper wall 212.

In view of the foregoing cooling air structural guiding features, a data storage array such as data storage system 200 is provisioned with a low power, low operating cost, low acoustic noise cooling regime. Embodiments provide for relatively “fresh” cooling air coming to each drive separately, thereby enabling for significantly low airflow rates and low pressure losses. Furthermore, embodiments enable “used” exhaust air to exit the drive array as rapidly as practical to avoid contaminating cool air.

### Hard Disk Drive Configuration

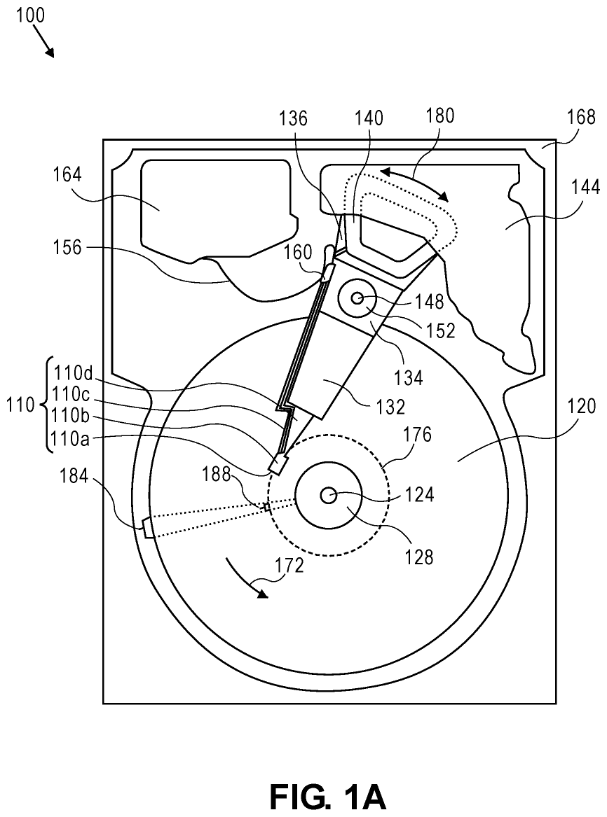

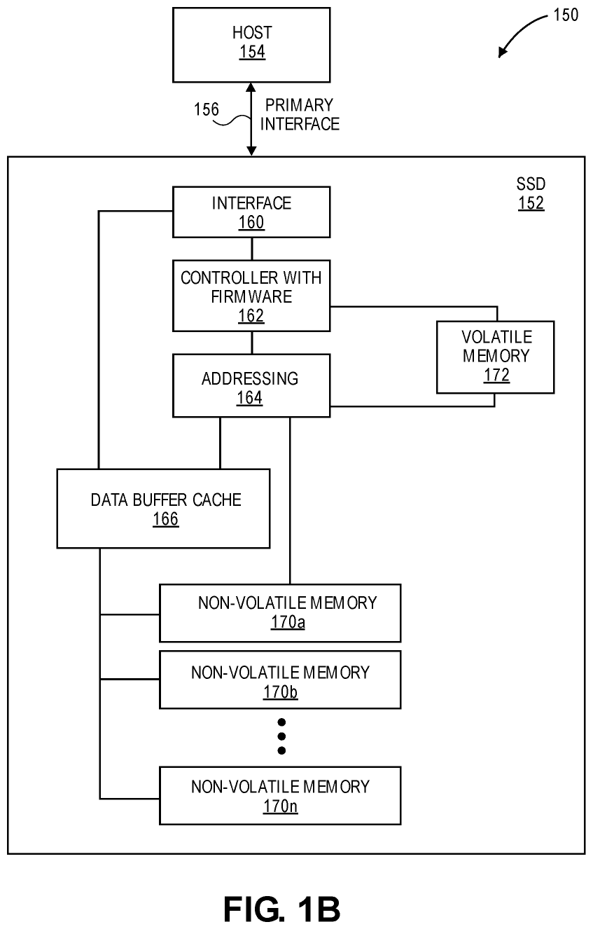

As discussed, embodiments may be used in the context of a data storage system in which multiple data storage devices (DSDs) including hard disk drives (HDDs) are employed. Thus, in accordance with an embodiment, a plan view illustrating an HDD 100 is shown in FIG. 1A to illustrate exemplary operating components.

FIG. 1A illustrates the functional arrangement of components of the HDD 100 including a slider 110b that includes a magnetic read-write head 110a. Collectively, slider 110b and head 110a may be referred to as a head slider. The HDD 100 includes at least one head gimbal assembly (HGA) 110 including the head slider, a lead suspension 110c attached to the head slider typically via a flexure, and a load beam 110d attached to the lead suspension 110c. The HDD 100 also includes at least one recording medium 120 rotatably mounted on a spindle 124 and a drive motor (not visible) attached to the spindle 124 for rotating the medium 120. The read-write head 110a, which may also be referred to as a transducer, includes a write element and a read element for respectively writing and reading information stored on the medium 120 of the HDD 100. The medium 120 or a plurality of disk media may be affixed to the spindle 124 with a disk clamp 128.

The HDD 100 further includes an arm 132 attached to the HGA 110, a carriage 134, a voice coil motor (VCM) that includes an armature 136 including a voice coil 140 attached to the carriage 134 and a stator 144 including a voice-coil magnet (not visible). The armature 136 of the VCM is attached to the carriage 134 and is configured to move the arm 132 and the HGA 110 to access portions of the medium 120, all collectively mounted on a pivot shaft 148 with an interposed pivot bearing assembly 152. In the case of an HDD having multiple disks, the carriage 134 may be referred to as an “E-block,” or comb, because the carriage is arranged to carry a ganged array of arms that gives it the appearance of a comb.

An assembly comprising a head gimbal assembly (e.g., HGA 110) including a flexure to which the head slider is coupled, an actuator arm (e.g., arm 132) and/or load beam to which the flexure is coupled, and an actuator (e.g., the VCM) to which the actuator arm is coupled, may be collectively referred to as a head-stack assembly (HSA). An HSA may, however, include more or fewer components than those described. For example, an HSA may refer to an assembly that further includes electrical interconnection components. Generally, an HSA is the assembly configured to move the head slider to access portions of the medium 120 for read and write operations.

With further reference to FIG. 1, electrical signals (e.g., current to the voice coil 140 of the VCM) comprising a write signal to and a read signal from the head 110a, are transmitted by a flexible cable assembly (FCA) 156 (or “flex cable”). Interconnection between the flex cable 156 and the head 110a may include an arm-electronics (AE) module 160, which may have an on-board pre-amplifier for the read signal, as well as other read-channel and write-channel electronic components. The AE module 160 may be attached to the carriage 134 as shown. The flex cable 156 may be coupled to an electrical-connector block 164, which provides electrical communication, in some configurations, through an electrical feed-through provided by an HDD housing 168. The HDD housing 168 (or “enclosure base” or “baseplate” or simply “base”), in conjunction with an HDD cover, provides a semi-sealed (or hermetically sealed, in some configurations) protective enclosure for the information storage components of the HDD 100.

Other electronic components, including a disk controller and servo electronics including a digital-signal processor (DSP), provide electrical signals to the drive motor, the voice coil 140 of the VCM and the head 110a of the HGA 110. The electrical signal provided to the drive motor enables the drive motor to spin providing a torque to the spindle 124 which is in turn transmitted to the medium 120 that is affixed to the spindle 124. As a result, the medium 120 spins in a direction 172. The spinning medium 120 creates a cushion of air that acts as an air-bearing on which the air-bearing surface (ABS) of the slider 110b rides so that the slider 110b flies above the surface of the medium 120 without making contact with a thin magnetic-recording layer in which information is recorded. Similarly in an HDD in which a lighter-than-air gas is utilized, such as helium for a non-limiting example, the spinning medium 120 creates a cushion of gas that acts as a gas or fluid bearing on which the slider 110b rides.

The electrical signal provided to the voice coil 140 of the VCM enables the head 110a of the HGA 110 to access a track 176 on which information is recorded. Thus, the armature 136 of the VCM swings through an arc 180, which enables the head 110a of the HGA 110 to access various tracks on the medium 120. Information is stored on the medium 120 in a plurality of radially nested tracks arranged in sectors on the medium 120, such as sector 184. Correspondingly, each track is composed of a plurality of sectored track portions (or “track sector”) such as sectored track portion 188. Each sectored track portion 188 may include recorded information, and a header containing error correction code information and a servo-burst-signal pattern, such as an ABCD-servo-burst-signal pattern, which is information that identifies the track 176. In accessing the track 176, the read element of the head 110a of the HGA 110 reads the servo-burst-signal pattern, which provides a position-error-signal (PES) to the servo electronics, which controls the electrical signal provided to the voice coil 140 of the VCM, thereby enabling the head 110a to follow the track 176. Upon finding the track 176 and identifying a particular sectored track portion 188, the head 110a either reads information from the track 176 or writes information to the track 176 depending on instructions received by the disk controller from an external agent, for example, a microprocessor of a computer system.

An HDD's electronic architecture comprises numerous electronic components for performing their respective functions for operation of an HDD, such as a hard disk controller (“HDC”), an interface controller, an arm electronics module, a data channel, a motor driver, a servo processor, buffer memory, etc. Two or more of such components may be combined on a single integrated circuit board referred to as a “system on a chip” (“SOC”). Several, if not all, of such electronic components are typically arranged on a printed circuit board that is coupled to the bottom side of an HDD, such as to HDD housing 168.

References herein to a hard disk drive, such as HDD 100 illustrated and described in reference to FIG. 1, may encompass an information storage device that is at times referred to as a “hybrid drive”. A hybrid drive refers generally to a storage device having functionality of both a traditional HDD (see, e.g., HDD 100) combined with solid-state storage device (SSD) using non-volatile memory, such as flash or other solid-state (e.g., integrated circuits) memory, which is electrically erasable and programmable. As operation, management and control of the different types of storage media typically differ, the solid-state portion of a hybrid drive may include its own corresponding controller functionality, which may be integrated into a single controller along with the HDD functionality. A hybrid drive may be architected and configured to operate and to utilize the solid-state portion in a number of ways, such as, for non-limiting examples, by using the solid-state memory as cache memory, for storing frequently-accessed data, for storing I/O intensive data, and the like. Further, a hybrid drive may be architected and configured essentially as two storage devices in a single enclosure, i.e., a traditional HDD and an SSD, with either one or multiple interfaces for host connection.

### Solid State Drive Configuration

As discussed, embodiments may be used in the context of a data storage system in which multiple data storage devices (DSDs) including solid-state drives (SSDs) are employed. Thus, FIG. 1B is a block diagram illustrating an example operating context with which embodiments of the invention may be implemented. FIG. 1B illustrates a generic SSD architecture 150, with an SSD 152 communicatively coupled with a host 154 through a primary communication interface 156. Embodiments are not limited to a configuration as depicted in FIG. 1B, rather, embodiments may be implemented with SSD configurations other than that illustrated in FIG. 1B. For example, embodiments may be implemented to operate in other environments that rely on non-volatile memory storage components for writing and reading of data.

Host 154 broadly represents any type of computing hardware, software, or firmware (or any combination of the foregoing) that makes, among others, data I/O requests or calls to one or more memory device. For example, host 154 may be an operating system executing on a computer, a tablet, a mobile phone, or generally any type of computing device that contains or interacts with memory, such as host 350 (FIG. 3). The primary interface 156 coupling host 154 to SSD 152 may be, for example, a storage system's internal bus or a communication cable or a wireless communication link, or the like.

The example SSD 152 illustrated in FIG. 1B includes an interface 160, a controller 162 (e.g., a controller having firmware logic therein), an addressing 164 function block, data buffer cache 166, and one or more non-volatile memory components 170a, 170b-170n.

Interface 160 is a point of interaction between components, namely SSD 152 and host 154 in this context, and is applicable at the level of both hardware and software. This enables a component to communicate with other components via an input/output (I/O) system and an associated protocol. A hardware interface is typically described by the mechanical, electrical and logical signals at the interface and the protocol for sequencing them. Some non-limiting examples of common and standard interfaces include SCSI (Small Computer System Interface), SAS (Serial Attached SCSI), and SATA (Serial ATA).

An SSD 152 includes a controller 162, which incorporates the electronics that bridge the non-volatile memory components (e.g., NAND (NOT-AND) flash) to the host, such as non-volatile memory 170a, 170b, 170n to host 154. The controller is typically an embedded processor that executes firmware-level code and is an important factor in SSD performance.

Controller 162 interfaces with non-volatile memory 170a, 170b, 170n via an addressing 164 function block. The addressing 164 function operates, for example, to manage mappings between logical block addresses (LBAs) from the host 154 to a corresponding physical block address on the SSD 152, namely, on the non-volatile memory 170a, 170b, 170n of SSD 152. Because the non-volatile memory page and the host sectors are different sizes, an SSD has to build and maintain a data structure that enables it to translate between the host writing data to or reading data from a sector, and the physical non-volatile memory page on which that data is actually placed. This table structure or “mapping” may be built and maintained for a session in the SSD's volatile memory 172, such as DRAM (dynamic random-access memory) or some other local volatile memory component accessible to controller 162 and addressing 164. Alternatively, the table structure may be maintained more persistently across sessions in the SSD's non-volatile memory such as non-volatile memory 170a, 170b-170n.

Addressing 164 interacts with data buffer cache 166, in addition to non-volatile memory 170a, 170b-170n. Data buffer cache 166 of an SSD 152 typically uses DRAM as a cache, similar to the cache in hard disk drives. Data buffer cache 166 serves as a buffer or staging area for the transmission of data to and from the non-volatile memory components, as well as serves as a cache for speeding up future requests for the cached data. Data buffer cache 166 is typically implemented with volatile memory so the data stored therein is not permanently stored in the cache, i.e., the data is not persistent.

Finally, SSD 152 includes one or more non-volatile memory 170a, 170b-170n components. For a non-limiting example, the non-volatile memory components 170a, 170b-170n may be implemented as flash memory (e.g., NAND or NOR flash), or other types of solid-state memory available now or in the future. The non-volatile memory 170a, 170b-170n components are the actual memory electronic components on which data is persistently stored. The non-volatile memory 170a, 170b-170n components of SSD 152 can be considered the analogue to the hard disks in hard-disk drive (HDD) storage devices.

Furthermore, references herein to a data storage device may encompass a multi-medium storage device (or “multi-medium device”, which may at times be referred to as a “multi-tier device” or “hybrid drive”). A multi-medium storage device refers generally to a storage device having functionality of both a traditional HDD (see, e.g., HDD 100) combined with an SSD (see, e.g., SSD 150) using non-volatile memory, such as flash or other solid-state (e.g., integrated circuits) memory, which is electrically erasable and programmable. As operation, management and control of the different types of storage media typically differ, the solid-state portion of a hybrid drive may include its own corresponding controller functionality, which may be integrated into a single controller along with the HDD functionality. A multi-medium storage device may be architected and configured to operate and to utilize the solid-state portion in a number of ways, such as, for non-limiting examples, by using the solid-state memory as cache memory, for storing frequently-accessed data, for storing I/O intensive data, for storing metadata corresponding to payload data (e.g., for assisting with decoding the payload data), and the like. Further, a multi-medium storage device may be architected and configured essentially as two storage devices in a single enclosure, i.e., a traditional HDD and an SSD, with either one or multiple interfaces for host connection.

### Extensions and Alternatives

In the foregoing description, embodiments of the invention have been described with reference to numerous specific details that may vary from implementation to implementation. Therefore, various modifications and changes may be made thereto without departing from the broader spirit and scope of the embodiments. Thus, the sole and exclusive indicator of what is the invention, and is intended by the applicants to be the invention, is the set of claims that issue from this application, in the specific form in which such claims issue, including any subsequent correction. Any definitions expressly set forth herein for terms contained in such claims shall govern the meaning of such terms as used in the claims. Hence, no limitation, element, property, feature, advantage or attribute that is not expressly recited in a claim should limit the scope of such claim in any way. The specification and drawings are, accordingly, to be regarded in an illustrative rather than a restrictive sense.

In addition, in this description certain process steps may be set forth in a particular order, and alphabetic and alphanumeric labels may be used to identify certain steps. Unless specifically stated in the description, embodiments are not necessarily limited to any particular order of carrying out such steps. In particular, the labels are used merely for convenient identification of steps, and are not intended to specify or require a particular order of carrying out such steps.

What is claimed is:

1. A data storage system comprising:
a plurality of data storage devices;
an enclosure in which the data storage devices are housed in a plurality of rows;
a first funnel structure extending from a floor of the enclosure and within which at least part of a first row of data storage devices is positioned, the first funnel structure having a first width and configured to direct airflow past the first row of data storage devices to a first central exhaust channel; and
a second funnel structure extending from the floor of the enclosure and within which at least part of a second row of data storage devices is positioned, the second funnel structure having a second width greater than the first width and configured to direct airflow past the second row of data storage devices to a second central exhaust channel substantially colinear with the first exhaust channel.

2. The data storage system of claim 1, wherein the second exhaust channel is wider than the first exhaust channel.

3. The data storage system of claim 1, further comprising:
an upper wall structure positioned above the data storage devices and extending to an enclosure top, the upper wall structure separating a first set of rows of data storage devices, including the first and second rows, from a second set of rows of data storage devices, the upper wall structure comprising:
a deflector portion positioned over a first row of data storage devices of the second set of rows and configured to direct airflow from above down to the second set of rows of data storage devices.

4. The data storage system of claim 3, further comprising:
a third funnel structure extending from the floor of the enclosure and within which at least part of a first row of data storage devices of the second set of rows is positioned, the third funnel structure having a third width and configured to direct airflow past the first row of the second set of rows to a third central exhaust channel substantially colinear with the first and second central exhaust channels.

5. The data storage system of claim 3, the upper wall structure further comprising:
at least one side channel extending beyond the deflector portion in a direction toward a back of the enclosure, the side channel configured to direct airflow from above down to one or more successive rows of data storage devices, beyond the first row, of the second set of rows.

6. The data storage system of claim 5, further comprising:
a third funnel structure extending from the floor of the enclosure and within which at least part of a first row of data storage devices of the second set of rows is positioned, the third funnel structure having a third width and configured to direct airflow past the first row of the second set of rows to a third central exhaust channel; and
a fourth funnel structure extending from the floor of the enclosure and within which at least part of a second row of data storage devices of the second set of rows is positioned, the fourth funnel structure having a fourth width greater than the third width and configured to direct airflow past the second row of the second set of rows to a fourth central exhaust channel substantially colinear with the first, second, and third central exhaust channels.

7. The data storage system of claim 6, wherein:
the third exhaust channel is wider than the second exhaust channel; and
the fourth exhaust channel is wider than the third exhaust channel.

8. The data storage system of claim 3, further comprising:
a first ceiling structure over the first set of rows; and
a second ceiling structure over the second set of rows.

9. The data storage system of claim 8, the upper wall structure further comprising:
a central channel extending in a direction toward a front of the enclosure and over a cutout portion of the first ceiling structure, the central channel configured to receive exhaust airflow from first set of rows via the cutout portion.

10. The data storage system of claim 8, the second ceiling structure comprising:
at least one cutout portion configured to enable exhaust airflow from the second set of rows to above the second set of rows beyond the deflector portion of the upper wall structure in a direction toward a back of the enclosure.

11. The data storage system of claim 10, the at least one cutout portion of the second ceiling structure comprising:
a cutout portion corresponding to each of multiple rows of the second set of rows, each cutout portion positioned beyond a respective row in a direction toward the back of the enclosure and configured to enable exhaust airflow from the respective row.

12. The data storage system of claim 1, further comprising:
at least one input/output (I/O) module positioned in the first and/or second central exhaust channel.

13. The data storage system of claim 1, wherein the plurality of data storage devices comprises hard disk drives.

14. The data storage system of claim 1, wherein the plurality of data storage devices comprises solid-state drives.

15. A data storage system comprising:
a plurality of data storage devices housed in rows in an enclosure;
a series of funnel structures extending upward from a floor of the enclosure and within which a respective row of data storage devices is positioned, wherein the funnel structures are configured successively wider from a front toward a back of the enclosure to direct airflow past the respective row of data storage devices to a successively wider central exhaust channel; and
an upper wall structure comprising a deflector portion configured to direct airflow down to one or more rows of the data storage devices.

16. The data storage system of claim 15, wherein the upper wall structure further comprises:
side channels extending beyond the deflector portion in a direction toward the back of the enclosure, wherein each side channel is configured to direct airflow down to one or more successive rows of data storage devices beyond the deflector portion.

17. The data storage system of claim 15, further comprising:
at least one ceiling structure over one or more rows of the data storage devices.

18. The data storage system of claim 17, wherein the upper wall structure further comprises:
a central channel extending in a direction from the deflector portion toward the front of the enclosure and over a cutout portion of a ceiling structure, wherein the central channel is configured to receive exhaust airflow from one or more rows of the data storage devices via the cutout portion.

19. The data storage system of claim 17, wherein at least one ceiling structure comprises:
at least one cutout portion beyond the deflector portion and configured to enable exhaust airflow from a row of the data storage devices to above the row in a direction toward the back of the enclosure.

20. A rack-mountable data storage system comprising:
a plurality of data storage devices housed in rows in a rack-mountable enclosure, the data storage devices comprising:
a plurality of disk media rotatably mounted on a spindle,
means for reading from and writing to the disk media, and
means for moving the means for reading and writing to access portions of the disk media;
a series of funnel structures extending upward from a floor of the enclosure and within which a respective row of data storage devices is positioned, wherein the funnel structures are configured successively wider from a front toward a back of the enclosure to direct airflow past the respective row of data storage devices to a successively wider central exhaust channel;
an upper wall structure comprising:
a deflector portion configured to direct airflow from above down to one or more rows of the data storage devices,
side channels extending beyond the deflector portion in a direction toward the back of the enclosure, wherein each side channel is configured to direct airflow down to one or more successive rows of data storage devices beyond the deflector portion, and
a central channel extending in a direction from the deflector portion toward the front of the enclosure and over a cutout portion of a first ceiling structure over one or more rows of the data storage devices, wherein the central channel is configured to receive exhaust airflow from the one or more rows via the cutout portion;
a second ceiling structure comprising at least one cutout portion configured to enable exhaust airflow from a row of the data storage devices behind the deflector portion of the upper wall structure and to above the row in a direction toward the back of the enclosure; and
a plurality of cooling fans for drawing airflow through the enclosure.
